(19) United States
(12) Patent Application Publication
(10) Pub. No.: US 2026/0060144 A1
(43) Pub. Date: Feb. 26, 2026

(54) OPTOELECTRONIC PACKAGE AND METHOD OF MANUFACTURING THE SAME

(71) Applicant: POWERTECH TECHNOLOGY INC., Hsinchu County (TW)

(72) Inventors: Chih Hao CHEN, Hsinchu County (TW); Shang-Yu CHANG CHIEN, Hsinchu County (TW)

(21) Appl. No.: 19/283,266

(22) Filed: Jul. 29, 2025

(30) Foreign Application Priority Data
Aug. 22, 2024 (TW) 113131554

(51) Int. Cl. H01L 25/16; H01L 21/48; H01L 21/56; H01L 23/31; H01L 23/538

(52) U.S. Cl. CPC H01L 25/167; H01L 21/4853; H01L 21/4857; H01L 21/565; H01L 23/3128; H01L 23/5383; H01L 23/5389

(57) ABSTRACT

An optoelectronic package includes a first and a second redistribution layers, a plurality of first and second metal pillars, an optoelectronic chip, a first and a second insulation layers and a processing component. The first metal pillars are disposed on the first redistribution layer. The optoelectronic chip includes a wiring layer, an active structure and a main layer. The wiring layer is electrically connected to the first metal pillars. The main layer is disposed between the wiring layer and the active structure. The first insulation layer disposed on the first redistribution layer covers the optoelectronic chip and the first metal pillars. The processing component is electrically connected to the first redistribution layer which is located between the processing component and the optoelectronic chip. The second metal pillars and the second insulation layer are disposed between the first redistribution layer and the second redistribution layer.

### CROSS-REFERENCE TO RELATED APPLICATION

This application claims priority to Taiwan Application Serial Number 113131554, filed Aug. 22, 2024, which is herein incorporated by reference in its entirety.

### BACKGROUND

### Technical Field

The present disclosure relates to an optoelectronic package and a method of manufacturing the same.

### Description of Related Art

Current mobile devices and wearable devices, such as laptops, smartphones, and smart watches, have optoelectronic components, for example, light emitting diodes (LEDs) or photosensors, so as to achieve the function of displaying images or sensing images. Many current mobile devices and wearable devices develop into a trend of reduction in size. The integration of the optoelectronic component with another electronic component can affect the sizes of the mobile device and the wearable device. Hence, in order to meet the trend of reduction in size, it is necessary to improve the integration of the current optoelectronic component with another electronic component.

### SUMMARY

At least one embodiment according to the present disclosure provides an optoelectronic package which facilitates mobile devices and wearable devices to develop into the trend of reduction in size.

At least one embodiment of the disclosure provides an optoelectronic package including a first redistribution layer, a plurality of first metal pillars, an optoelectronic chip, a first insulation layer, a processing component, a second redistribution layer, a plurality of second metal pillars, and a second insulation layer. The first metal pillars are disposed on the first redistribution layer, in which the first metal pillars are electrically connected to and directly touch the first redistribution layer. The optoelectronic chip includes a wiring layer, an active structure, and a main layer. The wiring layer is disposed on the first metal pillars, electrically connected to, and directly touches the first metal pillars. The active structure has an active face. The main layer is disposed between the wiring layer and the active structure, and has at least one through hole, in which the through hole extends from the active structure to the wiring layer. The first insulation layer is disposed on the first redistribution layer, and covers the optoelectronic chip and the first metal pillars, in which the first insulation layer exposes the active face. The processing component is electrically connected to the first redistribution layer, in which the first redistribution layer is located between the processing component and the optoelectronic chip. The processing component is located between the first redistribution layer and the second redistribution layer. The second metal pillars are connected to the first redistribution layer and the second redistribution layer. The second insulation layer disposed between the first redistribution layer and the second redistribution layer covers the processing component and the second metal pillars.

At least one embodiment of the disclosure provides a method of manufacturing the optoelectronic package including at least one optoelectronic chip. The at least one optoelectronic chip has an active face and a mounting surface located opposite to the active face apiece. Afterward, a plurality of first metal pillars are formed on the mounting surface. After the first metal pillars are formed on the mounting surface, at least one optoelectronic chip is disposed on a rigid substrate, in which the active face is located between the mounting surface and the rigid substrate. Afterward, a first insulation layer is formed on the rigid substrate, where the first insulation layer covers the optoelectronic chip and exposes an end surface of each of the first metal pillars. Afterward, a first redistribution layer and a plurality of second metal pillars are formed on the first insulation layer, where the first redistribution layer located between the second metal pillars and the first insulation layer is electrically connected to the second metal pillars and the first metal pillars. Afterward, at least one processing component is disposed on the first redistribution layer. Afterward, a second insulation layer is formed on the first redistribution layer, where the second insulation layer covers the processing component and exposes the end surface of each of the second metal pillars. Afterward, a second redistribution layer is formed on the second insulation layer, where the processing component is located between the first redistribution layer and the second redistribution layer, and the second redistribution layer is electrically connected to the second metal pillars.

Based on the above, since the first redistribution layer located between the processing component and the optoelectronic chip is electrically connected to the processing component and the optoelectronic chip, the distance between the optoelectronic chip and the processing component can be further shortened, thereby facilitating current mobile devices and wearable devices to meet the trend of reduction in size.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows.

FIG. 1A is a cross-sectional view of an optoelectronic package according to one embodiment of this disclosure.

FIG. 1B is an enlarged cross-sectional view of the optoelectronic chip in FIG. 1A.

FIGS. 2A to 2J are cross-sectional views of a method of manufacturing the optoelectronic package in FIG. 1A.

FIGS. 3A and 3B are cross-sectional views of a method of manufacturing the optoelectronic package according to another embodiment of this disclosure.

FIG. 3C is an enlarged cross-sectional view of the optoelectronic chip in FIG. 3B.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unusual proportions, and the quantity of some elements will be reduced. Accordingly, the description and explanation of the following embodiments are not limited to the quantity, sizes and shapes of the elements presented in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case which are mainly for illustration are intended neither to accurately depict the actual shape of the elements nor to limit the scope of patent applications in this case.

Moreover, the words, such as “about”, “approximately”, or “substantially”, appearing in the present disclosure not only cover the clearly stated values and ranges, but also include permissible deviation ranges as understood by those with ordinary knowledge in the technical field of the invention. The permissible deviation range can be caused by the error generated during the measurement, where the error is caused by such as the limitation of the measurement system or the process conditions. In addition, “about” may be expressed within one or more standard deviations of the values, such as within ±30%, ±20%, ±10%, or ±5%. The word “about”, “approximately” or “substantially” appearing in this text can choose an acceptable deviation range or a standard deviation according to optical properties, etching properties, mechanical properties or other properties, not just one standard deviation to apply all the optical properties, etching properties, mechanical properties and other properties.

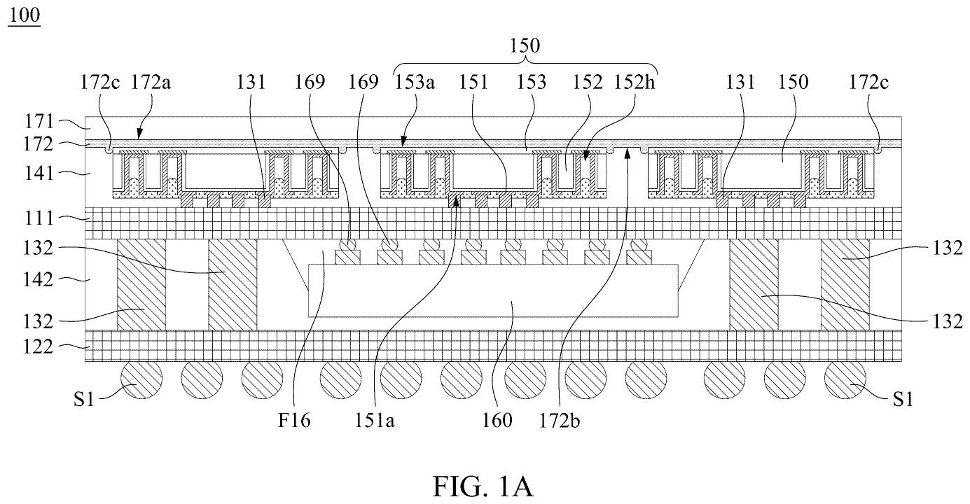

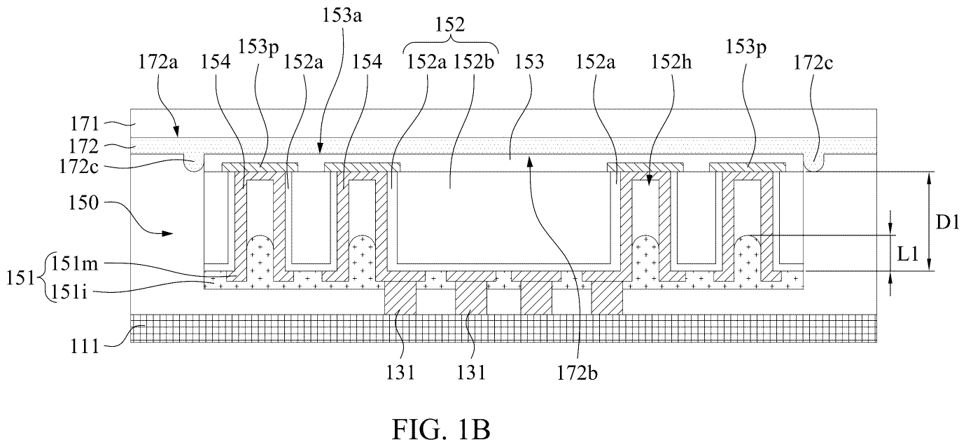

FIG. 1A is a cross-sectional view of an optoelectronic package according to one embodiment of this disclosure. Referring to FIG. 1A, an optoelectronic package 100 includes a first redistribution layer 111 and a plurality of first metal pillars 131. The first metal pillars 131 are disposed on the first redistribution layer 111, and the first metal pillars 131 are electrically connected to and directly touch the first redistribution layer 111.

The optoelectronic package 100 further includes a second redistribution layer 122 and a plurality of second metal pillars 132. The second metal pillars 132 are connected between the first redistribution layer 111 and the second redistribution layer 122, in which the second metal pillars 132 are electrically connected to and directly touch the first redistribution layer 111 and the second redistribution layer 122. In addition, the optoelectronic package 100 can further include a plurality of solder balls S1 connected to the second redistribution layer 122, where the second redistribution layer 122 is located between the first redistribution layer 111 and the solder balls S1, as shown in FIG. 1A. By using the solder balls S1, the optoelectronic package 100 can be mounted to an external circuit board, so that the optoelectronic package 100 is electrically connected to the external circuit board, where the external circuit board is a mother board or a packaging substrate, for example.

In the embodiment as shown in FIG. 1A, the size of the first metal pillars 131 is obviously different from the size of the second metal pillars 132. Specifically, the width and the length of each of the first metal pillars 131 can be less than the width and the length of each of the second metal pillars 132, as shown in FIG. 1A. Moreover, the first metal pillars 131 and the second metal pillars 132 can have a melting point higher than 300° C. apiece, i.e. higher than the melting point of lead-free solder, in which the material for making both the first metal pillars 131 and the second metal pillars 132 may include copper or nickel. Accordingly, when the first metal pillars 131 and the second metal pillars 132 are performed on reflow, the first metal pillars 131 ant the second metal pillars 132 cannot melt.

The optoelectronic package 100 further includes at least one optoelectronic chip 150 and at least one processing component 160. In the embodiment as shown in FIG. 1A, the optoelectronic package 100 includes a plurality of optoelectronic chips 150 and one processing component 160. However, there may be only one optoelectronic chip 150, and only one or at least two processing components 160 in a single optoelectronic package 100 of another embodiment. Hence, FIG. 1A does not limit the quantities of the optoelectronic chip 150 and the processing component 160.

In this embodiment, the processing component 160 may be a logic chip, such as Microcontroller Unit (MCU). The optoelectronic chip 150 may be a light-emitting component or a photo-sensing component. For example, the light-emitting component may be a LED chip, while the photo-sensing component may be a Complementary Metal-Oxide-Semiconductor (CMOS) image sensor or a Charge-Coupled Device (CCD).

The processing component 160 is located between the first redistribution layer 111 and the second redistribution layer 122. The first redistribution layer 111 is located between the processing component 160 and the optoelectronic chips 150. The processing component 160 is electrically connected to the first redistribution layer 111. Taking FIG. 1A for example, the processing component 160 can be mounted to the first redistribution layer 111 by flip-chip bonding, so the processing component 160 can be electrically connected to first redistribution layer 111 by using a plurality of solders 169, such as solder balls, in which an underfill F16 can fill a gap formed between the processing component 160 and the first redistribution layer 111.

The optoelectronic chips 150 have an active face 153a and a mounting surface 151a located opposite to the active face 153a apiece, in which the first metal pillars 131 are disposed on and connected to the mounting surface 151a, so that the optoelectronic chips 150 are electrically connected to the first metal pillars 131. Hence, the mounting surface 151a is located between the active face 153a and the first redistribution layer 111, while each of the optoelectronic chips 150 can be electrically connected to the first redistribution layer 111 via the first metal pillars 131. The active face 153a is a surface of the optoelectronic chip 150 for emitting or receiving light. When the optoelectronic chip 150 is a light-emitting component, the active face 153a is a light-emitting surface. When the optoelectronic chip 150 is a photo-sensing component, the active face 153a is a light-receiving surface.

The processing component 160 can be electrically connected to the external circuit board by the second metal pillars 132, the first redistribution layer 111, the second redistribution layer 122, and the solder balls S1, so that the electrical signals can be transmitted between the processing component 160 and the external circuit board. Each of the optoelectronic chips 150 is electrically connected to first redistribution layer 111 via the first metal pillars 131, so that a single first redistribution layer 111 can be electrically connected to the optoelectronic chips 150 and the processing component 160, where the first redistribution layer 111 is located between the optoelectronic chips 150 and the processing component 160.

As a result, the distance between the optoelectronic chip 150 and the processing component 160 can be shortened, so that it is not only to facilitate current mobile devices and wearable devices to meet the trend of reduction in size, but also to shorten an electrical signal transmission path between the optoelectronic chip 150 and the processing component 160, thereby improving the quality of the optoelectronic package 100 with respect to the electrical signal.

The optoelectronic package 100 further includes a first insulation layer 141 and a second insulation layer 142. The first insulation layer 141 is disposed on the first redistribution layer 111 and covers the optoelectronic chips 150 and the first metal pillars 131. The first insulation layer 141 exposes the active faces 153a of the optoelectronic chips 150. That is, the first insulation layer 141 does not cover the active face 153a, so as to avoid preventing the optoelectronic chip 150 from emitting or sensing light. The second insulation layer 142 disposed between the first redistribution layer 111 and the second redistribution layer 122 covers the processing component 160 and the second metal pillars 132. In addition, the first insulation layer 141 and the second insulation layer 142 may be molding compounds.

The optoelectronic package 100 can further include a light-transmissive substrate 171 and an optical adhesive 172. The light-transmissive substrate 171 covers the optoelectronic chips 150 and the first insulation layer 141, while the optical adhesive 172 adheres between the light-transmissive substrate 171 and the optoelectronic chip 150. The optical adhesive 172 includes a first adhering surface 172a and a second adhering surface 172b disposed opposite to the first adhering surface, where the first adhering surface 172a adheres to the light-transmissive substrate 171, and the second adhering surface 172b adheres to the optoelectronic chips 150 and the first insulation layer 141.

In addition, the optical adhesive 172 further includes at least one ring protrusion 172c, in which FIG. 1A depicts a plurality of ring protrusions 172c for example. However, there may be only one ring protrusion 172c in another embodiment, so FIG. 1A does not limit the quantity of the ring protrusion 172c included by a single optical adhesive 172. Each of the ring protrusions 172c protrudes from the second adhering surface 172b, encloses and is adjacent to one of the optoelectronic chips 150. Hence, the ring protrusion 172c can help to secure the optoelectronic chip 150 to the optical adhesive 172, so as to avoid the relative movement between the optoelectronic chip 150 and the optical adhesive 172.

When each of the optoelectronic chips 150 is a light-emitting component, the optoelectronic chips 150 can emit a plurality of rays of light from the active face 153a to the optical adhesive 172 and the light-transmissive substrate 171, so that the rays emitted from the active face 153a of each optoelectronic chip 150 can pass through the optical adhesive 172 and the light-transmissive substrate 171, and then exit the optoelectronic package 100 from the light-transmissive substrate 171, where the light-transmissive substrate 171 may be a glass substrate or a sapphire substrate.

The optoelectronic chips 150 can emit light with various colors, such as red light, green light, and blue light. The optoelectronic package 100 can generate images by the previous light with various colors. Alternatively, the optoelectronic package 100 can be made into a light source module and emit light with a single color, such as white light, blue light, or ultraviolet light, in which the optoelectronic package 100 can be used for a backlight module of Liquid Crystal Display (LCD). When the optoelectronic package 100 emits blue light or ultraviolet light, the previous LCD has a Quantum Dot Color Filter (QDCF). When the optoelectronic package 100 emits white light, the previous LCD has a regular color filter without any photoexcitation material, such as quantum dot.

In the embodiment shown in FIG. 1A, the upper and lower surfaces of the light-transmissive substrate 171 are planes. However, in another embodiment, at least one of the upper and lower surfaces of the light-transmissive substrate 171 can form an optical microstructure, such as a plurality of microlenses or a plurality of prismatic columns. Accordingly, the light-transmissive substrate 171 can change the paths of the light rays emitted from each of the optoelectronic chip 150, thereby achieving a particular optical function. For example, the upper surface of the light-transmissive substrate 171, i.e. the surface away from the optical adhesive 172, can form the microlenses, so that the light-transmissive substrate 171 can converge the rays from the active faces 153a, so that the rays can be concentrated and emitted from the light-transmissive substrate 171.

The active faces 153a of the optoelectronic chips 150 are coplanar to each other. Specifically, the active faces 153a are substantially in the same plane. That is to say, in fact, at least two of the active faces 153a actually can be not located in the same plane within an allowable tolerance range, under the influence of process limitation. In other words, at least two of the active faces 153a can be slightly non-coplanar. Hence, the previous active faces 153a of the optoelectronic chips 150 coplanar to each other means that it allows the active faces 153a to be slightly non-coplanar.

When the optoelectronic chips 150 are light-emitting components and emit the light from their active faces 153a, and the thickness of the optical adhesive 172 is constant, the transmission paths of the rays, e.g. chief rays, emitted by the optoelectronic chips 150 in the optical adhesive 172 and the light-transmissive substrate 171 respectively are substantially equal. As a result, when the rays of light emitted by the optoelectronic chips 150 are exiting from the light-transmissive substrate 171, the degree to which the rays with the same color are absorbed by the optical adhesive 172 and the light-transmissive substrate 171 do not differ too much, so that the rays with the same color have the same or similar intensity, thereby helping to enhance the image quality of the optoelectronic package 100.

FIG. 1B is an enlarged cross-sectional view of the optoelectronic chip in FIG. 1A. Referring to FIG. 1A and FIG. 1B, the optoelectronic chips 150 may include a wiring layer 151, a main layer 152, an active structure 153 apiece. The wiring layer 151 disposed on the first metal pillars 131 is electrically connected to and directly touches the first metal pillars 131. The main layer 152 is disposed between the wiring layer 151 and the active structure 153. The main layer 152 can have a plurality of through holes 152h. The through holes 152h extend from the active structure 153 to the wiring layer 151, while any one of the through holes 152h and each of the first metal pillars 131 are non-coaxial, as shown in FIG. 1B.

The main layer 152 can be made of silicon wafer, and the through holes 152h can be formed by using Through Silicon Via (TSV) process. The main layer 152 may include an insulation layer 152a and a semiconductor layer 152b, in which the semiconductor layer 152b may be made of silicon, and the insulation layer 152a may be made of silicon oxide. The insulation layer 152a covers the outer surface of the semiconductor layer 152b. Taking FIG. 1B for example, the insulation layer 152a can completely cover the lower surface of the semiconductor layer 152b, and be distributed along the sidewall of each of the through holes 152h, where the insulation layer 152a can cover the semiconductor layer 152b conformally and form the sidewall of each of the through holes 152h, so the insulation layer 152a will not fill each of the through holes 152h. In addition, except for the sidewalls of the through holes 152h, the insulation layer 152a may not cover the side surface of the semiconductor layer 152b, as shown in FIG. 1B.

The active structure 153 is connected to the optical adhesive 172 and has an active face 153a which is covered and directly touched by the optical adhesive 172, in which the active structure 153 has a multilayer structure. For example, when the optoelectronic chip 150 is a LED, the active structure 153 can include a P-type doped semiconductor layer (not shown), a N-type doped semiconductor layer (not shown), and a quantum well layer (not shown) located between the P-type doped semiconductor layer and the N-type doped semiconductor layer.

The optoelectronic chips 150 can further include a plurality of metal tubes 154 apiece, where the metal tubes 154 are disposed in the through holes 152h and cover the sidewalls and the bottom surface of the through holes 152h. That is, the metal tubes 154 also cover the surfaces (e.g. lower surfaces) of pads 153p, so that the insulation layer 152a is not sandwiched between the pad 153p and the metal tube 154 that covers the previous pad 153p, as shown in FIG. 1B. In addition, the quantities of both the metal tubes 154 and the through holes 152h may be equal.

The metal tubes 154 are connected to the active structure 153 and the wiring layer 151, so that the wiring layer 151 can be electrically connected to the active structure 153 via the metal tubes 154. The metal tubes 154 and the wiring layer 151 can be formed in the same process (e.g. the same electroplating process), so the metal tubes 154 and the wiring layer 151 can be integrally formed into one. The active structure 153 can have a plurality of pads 153p. The metal tubes 154 are connected to the pads 153p respectively, in which each of the pads 153p may be an electrode, such as an anode or a cathode.

The wiring layer 151 can include an outer insulation layer 151i and a metal layer 151m. As seen in FIG. 1B, the metal layer 151m is a patterned film and disposed on the bottom of the main layer 152, where the metal layer 151m is connected to the metal tubes 154. The outer insulation layer 151i directly touches the main layer 152 and covers the metal layer 151m, where the metal layer 151m is sandwiched between the main layer 152 and a part of the outer insulation layer 151i. The material for making the outer insulation layer 151i may include polyimide (PI), and the outer insulation layer 151i is formed by curing.

The uncured outer insulation layer 151i has fluidity. Hence, the uncured outer insulation layer 151i can enter the through holes 152h in the process of forming the outer insulation layer 151i, so that the outer insulation layer 151i extends into the through holes 152h. In addition, the outer insulation layer 151i has a part extending into each through hole 152h, and the length L1 of the part is less than the depth D1 of each through hole 152h. A ratio of the length L1 to the depth D1 may range between 0.1 and 0.5, so the outer insulation layer 151i does not fill each of the through holes 152h.

It is necessary to note that in the embodiment shown in FIGS. 1A and 1B, the main layer 152 has a plurality of through holes 152h, and the optoelectronic chips 150 include a plurality of metal tubes 154 apiece. However, there may be only one metal tube 154 and only one through hole 152h in a single optoelectronic chip 150 of another embodiment. That is, one main layer 152 has only one through hole 152h, and one optoelectronic chip 150 includes only one metal tube 154. Hence, FIGS. 1A and 1B depict multiple through holes 152h and multiple metal tubes 154 just for example and do not limit the quantities of both the through hole 152h and the metal tube 154 in a single optoelectronic chip 150.

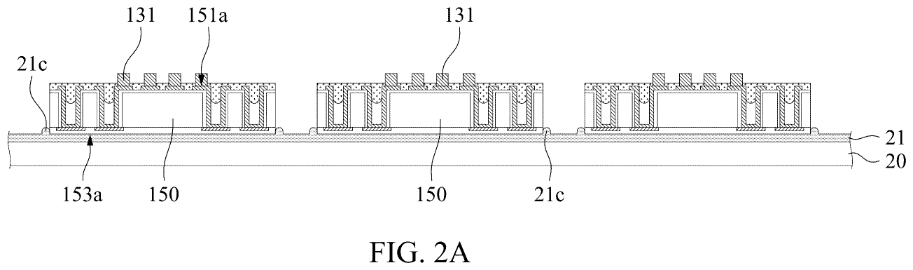

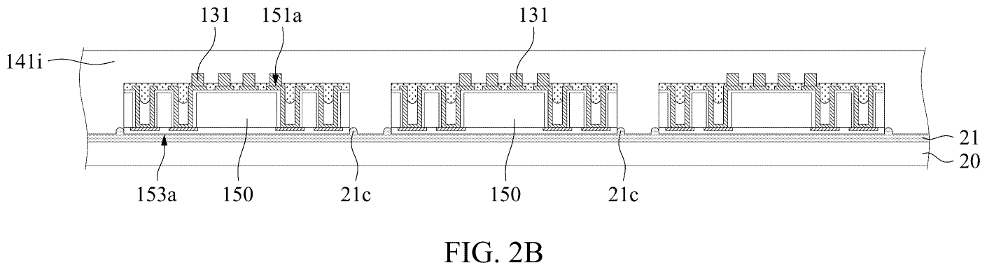

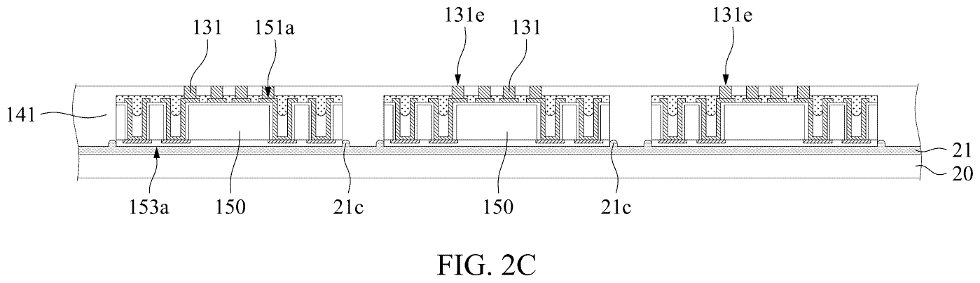

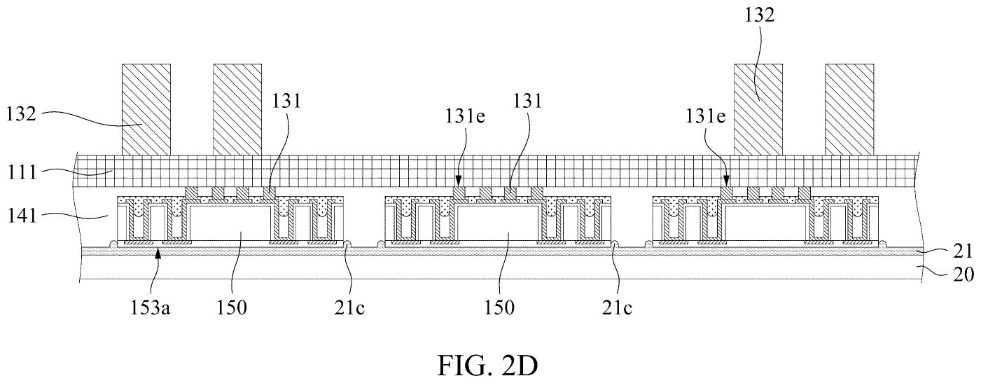

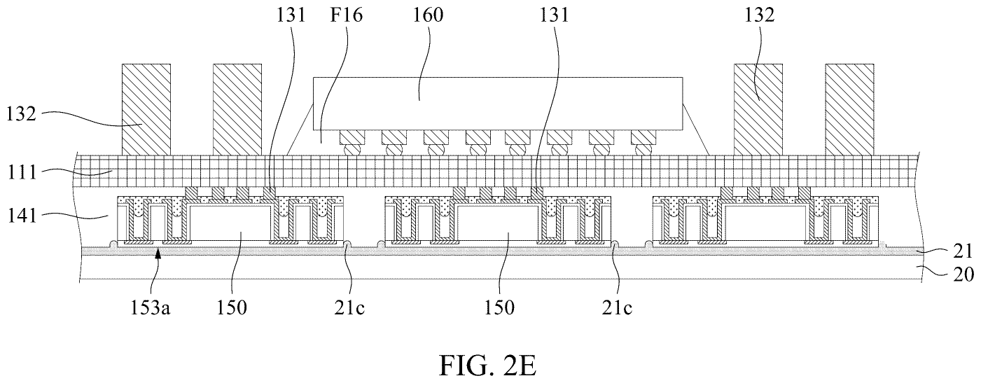

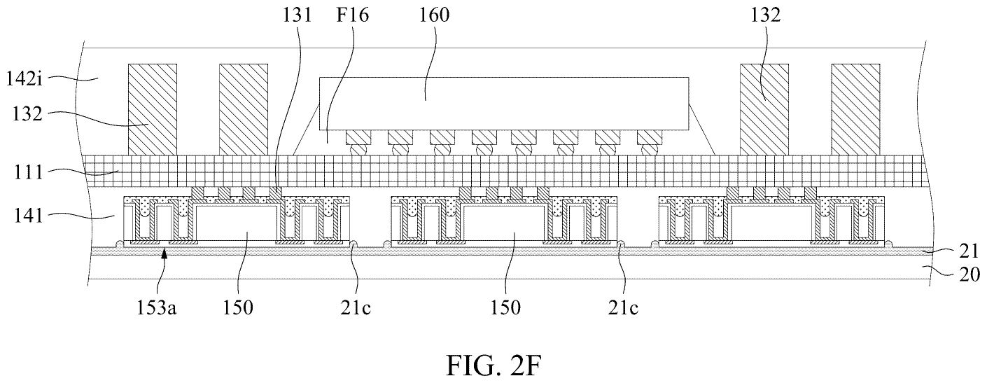

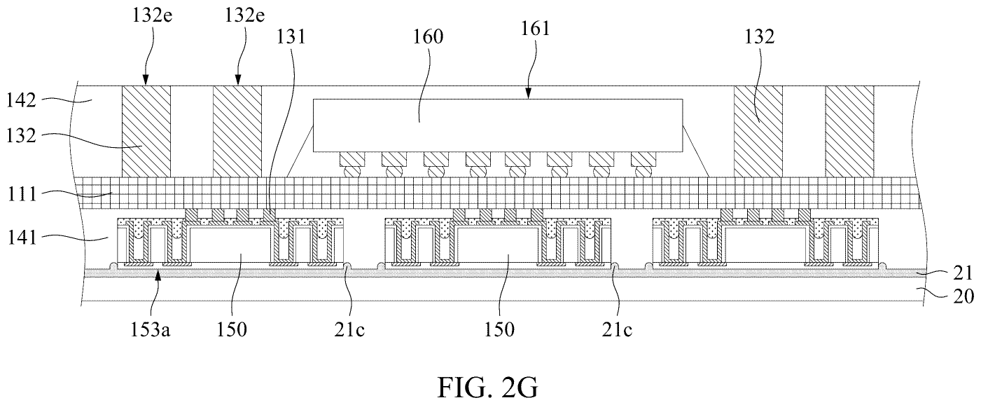

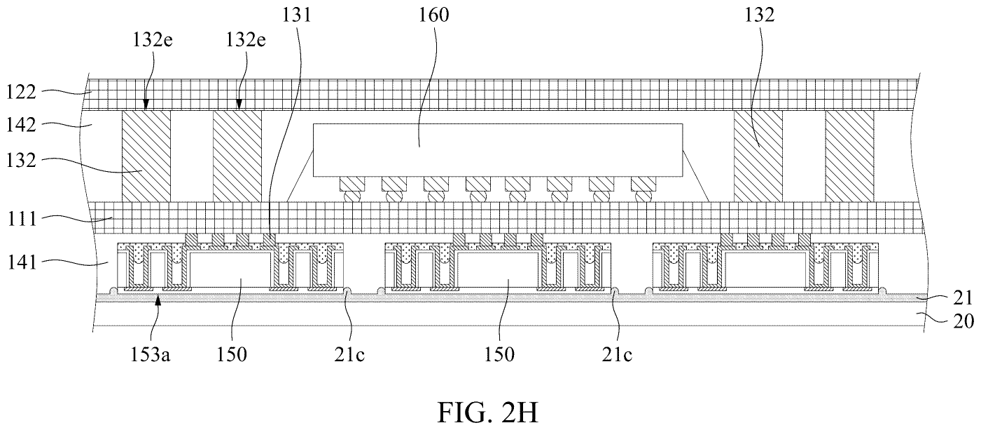

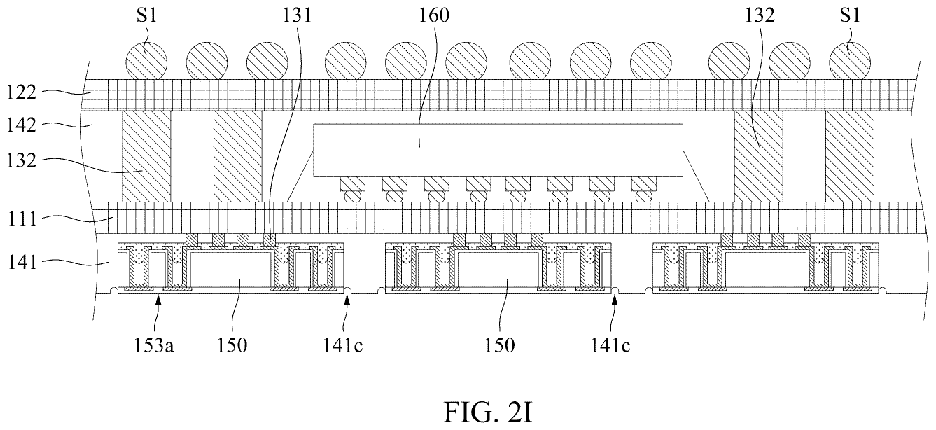

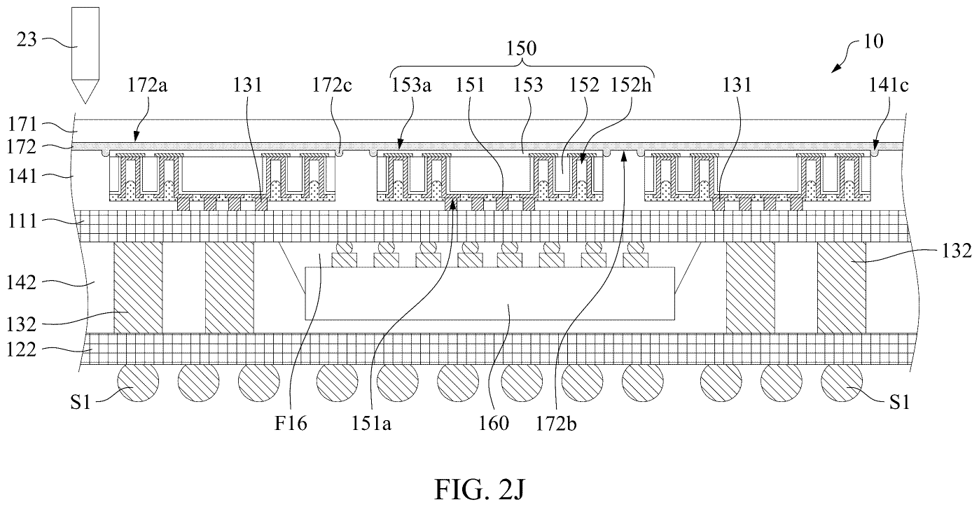

FIGS. 2A to 2J are cross-sectional views of a method of manufacturing the optoelectronic package in FIG. 1A. Referring to FIG. 2A, first, at least one optoelectronic chip 150 is provided. Taking FIG. 2A for example, a plurality of optoelectronic chips 150 are provided, in which the optoelectronic chips 150 has an active face 153a and a mounting surface 151a apiece.

Afterward, the optoelectronic chips 150 are disposed on the rigid substrate 20, where the rigid substrate 20 is such as a glass substrate, a metal plate, or a ceramic plate. The active face 153a of each optoelectronic chip 150 is located between the mounting surface 151a and the rigid substrate 20, as shown in FIG. 2A. In addition, before the optoelectronic chips 150 are disposed on the rigid substrate 20, a plurality of first metal pillars 131 have been formed on the mounting surfaces 151a of the optoelectronic chips 150, where the first metal pillars 131 can be formed by lithography and electroplating.

Disposing the optoelectronic chips 150 on the rigid substrate 20 includes the following steps. First, a release layer 21 is formed on the rigid substrate 20. Afterward, the optoelectronic chips 150 are disposed on the release layer 21, where the active face 153a of each optoelectronic chip 150 directly touches the release layer 21. That is, the release layer 21 covers the active face 153a of the optoelectronic chip 150. The release layer 21 can adhere to the optoelectronic chips 150 temporarily, where the release layer 21 may be release glue, such as optical release glue or thermal release glue.

Before the optoelectronic chips 150 are disposed on the release layer 21, the release layer 21 can have fluidity or plasticity. Hence, after the optoelectronic chips 150 are disposed on the release layer 21, each of the optoelectronic chips 150 presses the release layer 21, so that there is a ring protrusion 21c formed around each of the optoelectronic chips, as shown in FIG. 2A.

Referring to FIG. 2B and FIG. 2C, afterward, a first insulation layer 141 is formed on the rigid substrate 20, where the first insulation layer 141 covering the optoelectronic chips 150 and the ring protrusions 21c exposes the end surface 131e of each of the first metal pillars 131. In the embodiment shown in FIGS. 2B and 2C, forming the first insulation layer 141 can comprise the following steps.

Referring to FIG. 2B, first, a first molding layer 141i is formed on the rigid substrate 20, where the first molding layer 141i covers the mounting surfaces 151a and the side surfaces of the optoelectronic chips 150 and the first metal pillars 131, and further covers the partial surface of the release layer 21 and the ring protrusions 21c. Referring to FIGS. 2B and 2C, afterward, the first molding layer 141i is grinded to form the first insulation layer 141. The first molding layer 141i starts to be grinded from its outer surface away from the optoelectronic chip 150.

Taking FIG. 2B for example, the grinding starts from the upper surface of the first molding layer 141i, so as to remove the part of the first molding layer 141i which covers the mounting surface 151a, thereby reducing the thickness of the first molding layer 141i. After the first molding layer 141i is grinded, the end surface 131e of each of the first metal pillars 131 is exposed, as shown in FIG. 2C. It is worth mentioning that the part of at least one first metal pillar 131 (e.g., each first metal pillar 131) can be removed by grinding after grinding the first molding layer 141i, thereby resulting in reducing the height of the first metal pillar 131.

Referring to FIG. 2D, afterward, a first redistribution layer 111 and a plurality of second metal pillars 132 are formed on the first insulation layer 141, where the first redistribution layer 111 located between the second metal pillars 132 and the first insulation layer 141 is electrically connected to the second metal pillars 132 and the first metal pillars 131. The first redistribution layer 111 can be made directly on the first insulation layer 141 and the end surfaces 131e of the first metal pillars 131, so that the first metal pillars 131 are electrically connected to the first redistribution layer 111, and the end surfaces 131e directly touch the first redistribution layer 111.

After the first redistribution layer 111 is formed, the second metal pillars 132 are formed. The second metal pillars 132 can be formed by additive or semi-additive processes. That is, the second metal pillars 132 are formed by using electroplating with a mask layer (not shown), where the mask layer is such as a photoresist or dry film after development. Moreover, the second metal pillars 132 can be formed by subtractive process. That is, the second metal pillars 132 can be formed by using etching.

Referring to FIG. 2E, Afterward, at least one processing component 160 is disposed on the first redistribution layer 111. Taking FIG. 2E for example, FIG. 2E depicts a processing component 160 disposed on the first redistribution layer 111. However, in another embodiment, a plurality of processing components 160 can be disposed on the first redistribution layer 111, so that the optoelectronic package 100 in FIG. 1A can include the plurality of processing components 160. Alternatively, the manufacturing method of the present embodiment can manufacture a package panel including a plurality of optoelectronic packages 100. Hence. there may be multiple processing components 160 disposed on the first redistribution layer 111, and it does not limit only one processing component 160 disposed on the first redistribution layer 111.

The processing component 160 can be mounted to the first redistribution layer 111 by flip chip, in which the underfill F16 can fill the gap formed between the processing component 160 and the first redistribution layer 111. Referring to FIG. 2E, the height of each of the second metal pillars 132 is obviously greater than the height of the processing component 160. In other words, each of the second metal pillars 132 protrudes the upper surface of the processing component 160, as shown in FIG. 2E. In addition, in another embodiment, the height of each of the second metal pillars 132 can be equal to or less than the height of the processing component 160.

Referring to FIGS. 2F and 2G, afterward, a second insulation layer 142 is formed on the first redistribution layer 111, where the second insulation layer 142 covers the processing component 160 and exposes the end surface 132e of each second metal pillar 132. The formations of both the second insulation layer 142 and the first insulation layer 141 are similar, while the formation of the second insulation layer 142 can include the following steps in the embodiment as shown in FIGS. 2F and 2G.

Referring to FIG. 2F, first, a second molding layer 142i is formed on the first redistribution layer 111, in which the second molding layer 142i covers the processing component 160 and the second metal pillars 132. Referring to FIGS. 2F and 2G, afterward, the second molding layer 142i is grinded to form the second insulation layer 142 exposing the end surface 132e of each second metal pillar 132, as shown in FIG. 2G. The second molding layer 142i starts to be grinded from its outer surface away from the optoelectronic chip 150.

Taking FIG. 2F for example, the grinding starts from the upper surface of the second molding layer 142i, so as to remove the part of the second molding layer 142i which covers the processing component 160, thereby reducing the thickness of the second molding layer 142i and exposing the end surfaces 132e. Moreover, in the embodiment as shown in FIG. 2G, at least one second metal pillar 132 can be partially removed by grinding, while the grinded second molding layer 142 still covers the processing component 160.

It is necessary to note that in another embodiment, the second metal pillars 132 can be partially removed apiece to reduce the height of the second metal pillar 132 in the process of grinding the second molding layer 142i, so that the height of each second metal pillar 132 is equal to the height of the processing component 160, thereby exposing the end surfaces 132e of the second metal pillars 132 and the backside 161 of the processing component 160. In addition, since the height of each second metal pillar 132 can be equal to or less than the height of the processing component 160 in another embodiment, not only the end surface 132e of each second metal pillar 132 but also the backside 161 of the processing component 160 are exposed after the second molding layer 142i is grinded.

Referring to FIG. 2H, afterward, the second redistribution layer 122 is formed on the second insulation layer 142, where the processing component 160 is located between the first redistribution layer 111 and the second redistribution layer 122, and the second redistribution layer 122 is electrically connected to the second metal pillars 132. The second redistribution layer 122 can be made directly on the second insulation layer 142 and the end surfaces 132e of the second metal pillars 132, so that the second metal pillars 132 are electrically connected to the second redistribution layer 122, while the end surfaces 132e directly touch the second redistribution layer 122.

Referring to FIGS. 2H and 2I, after the second redistribution layer 122 is formed on the second insulation layer 142, the release layer 21 and the rigid substrate 20 are removed, where the rigid substrate 20 can be peeled off via the release layer 21. Since the release layer 21 can be release glue (e.g. optical release glue or thermal release glue), the release layer 21 can be irradiated or heated up, so that the rigid substrate 20 can be peeled off from the first insulation layer 141 and the active face 153a, so as to remove the release layer 21 and the rigid substrate 20. In addition, when the release layer 21 is optical release glue, the rigid substrate 20 can be a glass substrate, so that the light can pass through the glass substrate (i.e. rigid substrate 20) and then hit the release layer 21.

After the release layer 21 and the rigid substrate 20 are removed, the part of the first insulation layer 141 covering the ring protrusions 21c can form a plurality of grooves 141c, where the grooves 141c are adjacent to the optoelectronic chips 150 and enclose the active faces 153a, as shown in FIG. 2I. Afterward, the plurality of solder balls S1 can be disposed on the second redistribution layer 122. It is worth mentioning that in the present embodiment, the solder balls S1 can be disposed on the second redistribution layer 122 after removing the release layer 21 and the rigid substrate 20. However, in another embodiment, the solder balls S1 can be disposed on the second redistribution layer 122 before removing the release layer 21 and the rigid substrate 20.

Referring to FIG. 2J, after the rigid substrate 20 and the release layer 21 are removed, the light-transmissive substrate 171 adheres to the active faces 153a of the optoelectronic chips 150 by the optical adhesive 172, where FIG. 2J is drawn based on the inverted FIG. 2I. So far, the optoelectronic package 10 is basically complete. In addition, the optical adhesive 172 fills the grooves 141c, thereby forming the plurality of ring protrusions 172c in the grooves 141c.

The optoelectronic package 10 shown in FIG. 2J may be a package panel and include a plurality of optoelectronic packages 100 shown in FIG. 1A. Hence, after the light-transmissive substrate 171 adheres to the active face 153a, the optoelectronic package 10 in FIG. 2J can be diced by using a dicing tool 23 to perform singulation, thereby forming the plurality of optoelectronic packages 100 shown in FIG. 1A, in which the dicing tool 23 may be a cutter or a laser beam.

It is necessary to note that the embodiment shown in FIGS. 2A to 2J is illustrated with a package panel for example. In another embodiment, after the light-transmissive substrate 171 adheres to the active face 153a of the optoelectronic chip 150, the optoelectronic package 100 is complete immediately without dicing. In other words, the method disclosed in FIGS. 2A to 2J can be used for manufacturing a package unit (e.g. optoelectronic package 100) without singulation and not limited to manufacturing the package panel only.

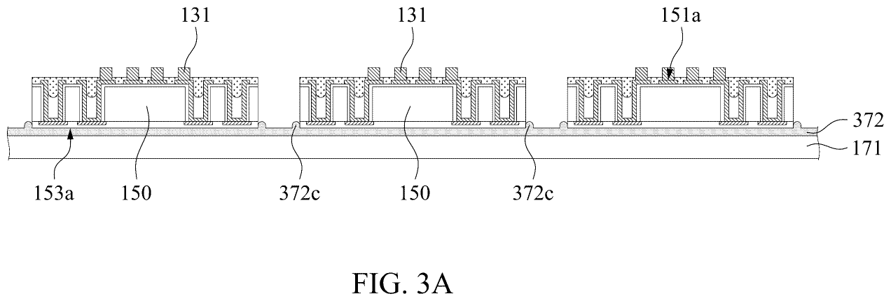

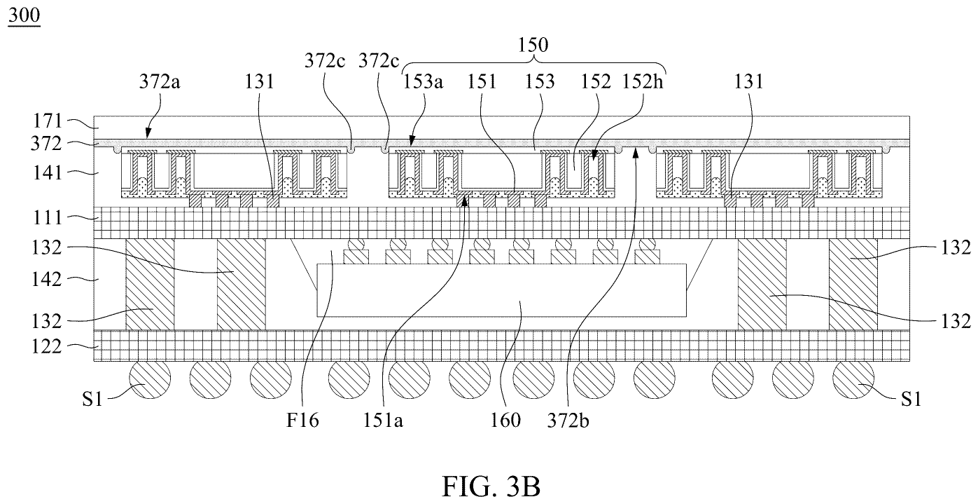

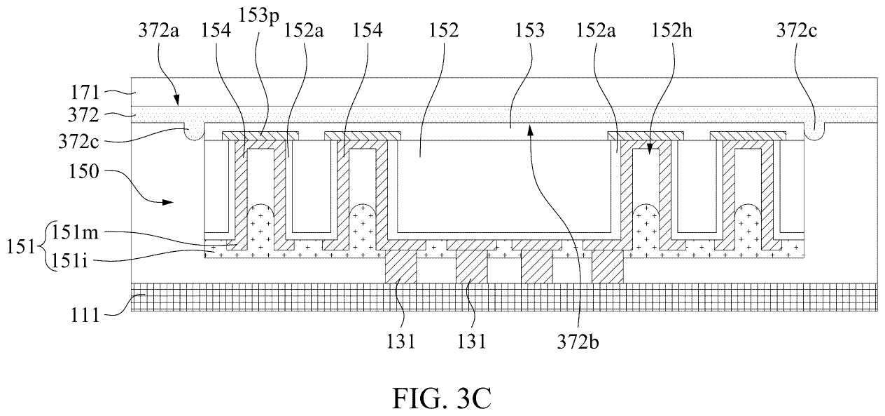

FIGS. 3A and 3B are cross-sectional views of a method of manufacturing the optoelectronic package according to another embodiment of this disclosure. FIG. 3B depicts an optoelectronic package 300 that is complete, while FIG. 3A depicts a process of the method of manufacturing the optoelectronic package 300. The manufacturing method of the optoelectronic package 300 is similar to the manufacturing method of the optoelectronic package 10 or 100 of FIGS. 2A to 2J. That is, the method of manufacturing the optoelectronic package 300 includes the steps of the previous embodiment. Accordingly, the following description mainly describes the difference of the optoelectronic package 300 from the optoelectronic packages 10 and 100 in structure and manufacture, while the same features and manufacturing processes of the optoelectronic packages 300, 10, and 100 will not be repeated and not be drawn in the drawings.

Referring to FIG. 3A, in the manufacturing method of the present embodiment, the optoelectronic chips 150 are disposed on the rigid substrate after providing one or more optoelectronic chips 150 and forming a plurality of first metal pillars 131 on the mounting surfaces 151a of the optoelectronic chips 150. Unlike the manufacturing method of the previous embodiment, the rigid substrate in FIG. 3A is the light-transmissive substrate 171, while disposing the optoelectronic chips 150 on the light-transmissive substrate 171 includes the following steps.

First, an optical adhesive 372 is formed on the light-transmissive substrate 171, in which the materials of the optical adhesives 372 and 172 are the same. Afterward, the optical adhesive 372 adheres to the optoelectronic chips 150, where the optical adhesive 372 adheres to the active face 153a of each optoelectronic chip 150. The formation of the optical adhesives 172 and 372 includes curing, while the optical adhesives 172 and 372 before curing have fluidity or plasticity. Accordingly, in the process that the optical adhesive 372 adheres to the optoelectronic chips 150, each of the optoelectronics chips 150 presses the optical adhesive 372, so that a ring protrusion 372c is formed around each of the optoelectronic chips 150, as shown in FIG. 3A. Moreover, the optical adhesives 172 and 372 also can be made of thermal plastic material, so that the optical adhesives 172 and 372 after curing can maintain a certain degree of plasticity.

Referring to FIG. 3B, after the optical adhesive 372 adheres to the optoelectronic chips 150 and the light-transmissive substrate 171, the processes as disclosed in FIGS. 2B to 2H can be performed, thereby completing the optoelectronic package 300, where the processes and steps disclosed in FIGS. 2B to 2H are described in the previous embodiment and thus not repeated in the following. In addition, the optical adhesive 372 can adhere each of the optoelectronic chips 150 to the light-transmissive substrate 171 permanently. Hence, unlike the previous embodiment, the manufacturing method of the present embodiment does not include removing the rigid substrate (i.e. light-transmissive substrate 171) as shown in FIG. 2I. That is, the light-transmissive substrate 171 in the present embodiment will not be removed.

FIG. 3C is an enlarged cross-sectional view of the optoelectronic chip in FIG. 3B. Referring to FIG. 3B and FIG. 3C, the optical adhesive 372 of the present embodiment includes a first adhering surface 372a, a second adhering surface 372b, and at least one ring protrusion 372c, where FIG. 3B depicts a plurality of ring protrusions 372c for example. However, there may be only one ring protrusion 372c in another embodiment, so that FIG. 3B does not limit the quantity of the ring protrusion 372c included by a single optical adhesive 372. Each of the ring protrusions 372c protrudes from the second adhering surface 372b, encloses and is adjacent to one of the optoelectronic chips 150. Hence, the ring protrusion 372c can help to secure the optoelectronic chip 150 to the optical adhesive 372, so as to avoid the relative movement between the optoelectronic chip 150 and the optical adhesive 372.

Consequently, since the first redistribution layer located between the processing component and the optoelectronic chip is electrically connected to the processing component and the optoelectronic chip, that is, the single first redistribution layer is electrically connected to the optoelectronic chip and the processing component, both the optoelectronic chip and the processing component can be electrically connected to each other via the first redistribution layer, thereby further shortening the distance between the optoelectronic chip and the processing component, and facilitating current mobile devices and wearable devices to meet the trend of reduction in size.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An optoelectronic package, comprising:
a first redistribution layer;
a plurality of first metal pillars, disposed on the first redistribution layer, wherein the plurality of first metal pillars are electrically connected to and directly touch the first redistribution layer;
an optoelectronic chip, comprising:
a wiring layer, disposed on the plurality of first metal pillars, electrically connected to, and directly touching the plurality of first metal pillars;
an active structure, having an active face;
a main layer, disposed between the wiring layer and the active structure, and having at least one through hole, wherein the at least one through hole extends from the active structure to the wiring layer;
a first insulation layer, disposed on the first redistribution layer and covering the optoelectronic chip and the first metal pillars, wherein the first insulation layer exposes the active face;
a processing component, electrically connected to the first redistribution layer, wherein the first redistribution layer is located between the processing component and the optoelectronic chip;
a second redistribution layer, wherein the processing component is located between the first redistribution layer and the second redistribution layer;
a plurality of second metal pillars, connected between the first redistribution layer and the second redistribution layer; and
a second insulation layer, disposed between the first redistribution layer and the second redistribution layer, wherein the second insulation layer covers the processing component and the plurality of second metal pillars.

2. The optoelectronic package of claim 1, wherein the at least one through hole and each of the first metal pillars are non-coaxial.

3. The optoelectronic package of claim 2, wherein the optoelectronic chip further comprises:
at least one metal tube, disposed in at least one through hole, and covering a sidewall of the at least one through hole, wherein the at least one metal tube is connected to the active structure and the wiring layer.

4. The optoelectronic package of claim 1, wherein the optoelectronic chip further comprises:
at least one metal tube, disposed in at least one through hole, and covering a sidewall of the at least one through hole, wherein the at least one metal tube is connected to the active structure and the wiring layer.

5. The optoelectronic package of claim 1, wherein the wiring layer comprises an outer insulation layer directly touching the main layer and extending into the at least one through hole, wherein the outer insulation layer has a part extending into the at least one through hole, and a length of the part is less than a depth of the at least one through hole.

6. The optoelectronic package of claim 5, wherein a ratio of the length of the part extending into the at least one through hole to the depth of the at least one through hole ranges between 0.1 and 0.5.

7. The optoelectronic package of claim 1, further comprising:
a light-transmissive substrate, covering the optoelectronic chip and the first insulation layer; and
an optical adhesive, adhering between the light-transmissive substrate and the optoelectronic chip.

8. The optoelectronic package of claim 7, wherein the optical adhesive comprises:
a first adhering surface, adhering to the light-transmissive substrate;
a second adhering surface, disposed opposite to the first adhering surface, and adhering to the optoelectronic chip and the first insulation layer; and
a ring protrusion, protruding from the second adhering surface, enclosing, and adjacent to the optoelectronic chip.

9. The optoelectronic package of claim 7, comprising a plurality of optoelectronic chips, wherein a plurality of active faces of the plurality of optoelectronic chips are coplanar to each other.

10. The optoelectronic package of claim 1, comprising a plurality of optoelectronic chips, wherein a plurality of active faces of the plurality of optoelectronic chips are coplanar to each other.

11. The optoelectronic package of claim 10, further comprising:
a light-transmissive substrate, covering the optoelectronic chips and the first insulation layer; and
an optical adhesive, adhering between the light-transmissive substrate and the optoelectronic chips, and comprising:
a first adhering surface, adhering to the light-transmissive substrate;
a second adhering surface, disposed opposite to the first adhering surface, and adhering to the optoelectronic chip and the first insulation layer; and
a plurality of ring protrusions, protruding from the second adhering surface, wherein each of the ring protrusions encloses and is adjacent to one of the optoelectronic chips.

12. The optoelectronic package of claim 1, wherein each of the first metal pillars and each of the second metal pillars 132 have a melting point higher than 300° C. apiece.

13. The optoelectronic package of claim 12, wherein the optoelectronic chip is a light-emitting component or a photo-sensing component.

14. The optoelectronic package of claim 1, wherein the optoelectronic chip is a light-emitting component or a photo-sensing component.

15. A method of manufacturing an optoelectronic package, comprising:
providing at least one optoelectronic chip, wherein the at least one optoelectronic chip has an active face and a mounting surface located opposite to the active face apiece;
forming a plurality of first metal pillars on the mounting surface;
after forming the plurality of first metal pillars on the mounting surface, disposing at least one optoelectronic chip on a rigid substrate, wherein the active face is located between the mounting surface and the rigid substrate;
forming a first insulation layer on the rigid substrate, wherein the first insulation layer covers the at least one optoelectronic chip and exposes an end surface of each of the plurality of first metal pillars;
forming a first redistribution layer and a plurality of second metal pillars on the first insulation layer, wherein the first redistribution layer located between the plurality of second metal pillars and the first insulation layer is electrically connected to the plurality of second metal pillars and the plurality of first metal pillars;
disposing at least one processing component on the first redistribution layer;
forming a second insulation layer on the first redistribution layer, wherein the second insulation layer covers at least one processing component and exposes an end surface of each of the second metal pillars; and
forming a second redistribution layer on the second insulation layer, wherein the at least one processing component is located between the first redistribution layer and the second redistribution layer, and the second redistribution layer is electrically connected to the plurality of second metal pillars.
